(19) United States
(12) Patent Application Publication
(10) Pub. No.: US 2016/0066477 A1
(43) Pub. Date: Mar. 3, 2016

(54) THERMAL MANAGEMENT STAND FOR PORTABLE COMPUTING DEVICE

(71) Applicants: Baomin Liu, Austin, TX (US); Christopher Jaggers, Austin, TX (US)

(72) Inventors: Baomin Liu, Austin, TX (US); Christopher Jaggers, Austin, TX (US)

(21) Appl. No.: 14/473,046

(22) Filed: Aug. 29, 2014

(51) Int. Cl. H05K 7/20; B23P 15/26; F25B 21/02

(52) U.S. Cl. CPC H05K 7/20509; H05K 7/20336; F25B 21/02; B23P 15/26

(57) ABSTRACT

Various portable computing device thermal management stands and methods of using and making the same are disclosed. In one aspect, a stand for supporting and thermally managing a portable computing device that has a first surface is provided. The stand includes a support plate that has a second surface to contact the first surface of the computing device and transfer heat from the computing device by conduction. The stand is operable to transfer heat received from the computing device to the ambient environment. A wall coupled to the support plate may be used to bear against a member supporting the stand to provide stability.

### BACKGROUND OF THE INVENTION

1. Field of the Invention

This invention relates generally to electronic devices, and more particularly to a system for providing thermal management of portable electronic devices.

2. Description of the Related Art

Handheld computing devices, such as smart phones, tablet computers and e-book readers, present significant thermal management challenges. There is ongoing user demand for devices that are not only smaller form factor for greater portability but also powerful enough to handle video and other computing intensive tasks. The provision for significant computing power in a relatively small form device often translates into the need for significant thermal management of the heat dissipating devices.

One common solution used to transfer heat from a processor in a small form device includes the use of a heat spreader that is in thermal contact with the processor. The heat spreader is in turn, in thermal contact with a heat exchanger via a heat pipe or other structure. The heat exchanger often includes an air mover such as a fan. One example of such a conventional device is the model LE1700 manufactured by Motion Computing, Inc. The LE1700 includes a very thin fan connected thermally to a heat spreader mounted to the microprocessor by way of a heat pipe. The fan vents air to the external ambient environment by way of a small vent. An Acer model Iconia is another conventional example.

There is an ongoing push to reduce the size, weight and cost of portable computing devices. Weight and form reductions can make portable devices easier to carry, hold and manipulate, and thus improve the user experience. However, there remains user demand for computing performance even if form factors are reduced. To cool such devices, some conventional designs use passive only thermal management. However, passive cooling limits the performance of the platform to the thermal limits of the system. Another conventional solution involves the use of an after-market add-on fan arrangement. The arrangement uses a fan to blow air across the exterior of the computing device. This conventional design cannot move air across a heat dissipating component inside the computing device.

Another potential pitfall associated with the conventional thermal management system just described is the issue of both acoustic and electrical noise associated with a cooling fan. Such issues can be reduced though not completely eliminated through the use of appropriate noise filtering circuitry and fan and vent design. However, there remains the issue of power consumption to run the fan.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of thermally managing a portable computing device is provided that includes placing the portable computing device on a stand that has a support plate with a first surface. The computing device is placed such that a second surface of the portable computing device contacts the first surface of the support plate. Heat is transferred from the computing device to the support plate by conduction and heat received by the stand from the computing device is transferred to the ambient environment.

In accordance with another aspect of an embodiment of the present invention, a method of manufacturing a stand for supporting and thermally managing a portable computing device that has a first surface is provided. The method includes providing a support plate having a second surface to contact the first surface of the computing device and transfer heat from the computing device by conduction. A first wall is coupled to the support plate. The first wall is adapted to bear against a member supporting the stand. The stand is operable to transfer heat received from the computing device to the ambient environment.

In accordance with another aspect of an embodiment of the present invention, a stand for supporting and thermally managing a portable computing device that has a first surface is provided. The stand includes a support plate that has a second surface to contact the first surface of the computing device and transfer heat from the computing device by conduction. The stand is operable to transfer heat received from the computing device to the ambient environment.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a thermal management stand that is designed to provide physical support and thermal management for a portable computing device;

FIG. 2 is a sectional view of FIG. 1 taken at section 2-2;

FIG. 3 is a sectional view like FIG. 2 but depicting an exemplary thermal management stand seated on a member or electronic device;

FIG. 4 is a sectional view like FIG. 3, but depicting an alternate exemplary thermal management stand;

FIG. 5 is a sectional view like FIG. 3, but depicting another alternate exemplary thermal management stand;

FIG. 6 is a pictorial view depicting another alternate exemplary embodiment of a thermal management stand; and

FIG. 7 is a pictorial view of two additional alternate embodiments of a thermal management stand.

### DETAILED DESCRIPTION OF SPECIFIC EMBODIMENTS

Various embodiments of a stand for supporting and thermally managing a portable computing device are disclosed. One variant of the stand is fanless and includes a support plate that has a surface to contact an opposing surface of the portable computing device and transfer heat from the computing device by conduction. The stand is operable to transfer heat received from the computing device to the ambient environment by radiation and convection. The stand may include a wall coupled to the support plate to bear against a member supporting the stand, such as a television or computing monitor. Various features may be added to the stand to aid in heat transfer without raising acoustic issues, such as thermoelectric coolers, thermally emissive coatings, heat sinks and surface texturing. Additional details will now be described.

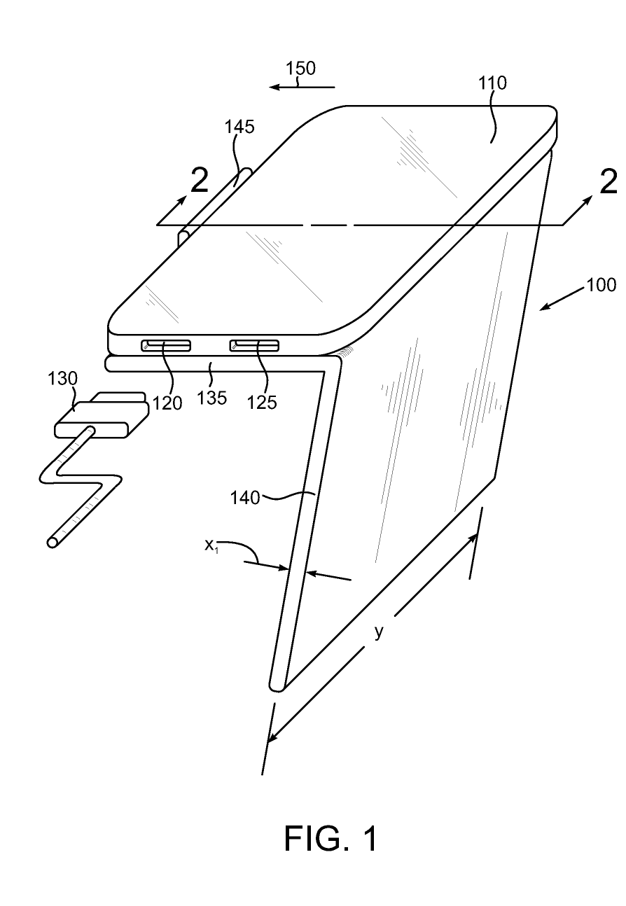

In the drawings described below, reference numerals are generally repeated where identical elements appear in more than one figure. Turning now to the drawings, and in particular to FIG. 1, therein is shown a pictorial view of an exemplary embodiment of a thermal management stand 100 that is designed to provide physical support and thermal management for a portable computing device 110. The computing device 110 may be a computer, a portable phone, a game console, or virtually any other electronic device that may benefit from thermal management. The computing device 110 may include one or more ports 120 and 125. The ports 120 and 125 may be any of the myriad of different types of input, output and input/output ports used in computing devices. Examples include USB ports, audio jacks, video jacks, power ports, network ports, or virtually any other type of input/output port. In an exemplary embodiment, the port 120 may be a mini-display port designed to receive a mini-display port cable 130.

As noted above, the stand 100 provides both physical support for the computing device 110 as well as thermal management. In this respect, the stand 100 may include a support plate 135 upon which the computing device 110 may seat. The support plate 135 may be integrally formed with or otherwise attached to a downwardly extending wall 140. An optional lip 145 may be connected or integrally formed with the plate 135 to prevent the computing device 110 from sliding off of the support plate 135 by movement in the direction of the arrow 150 for example. In the illustrative embodiment, the footprint of the support plate 135 generally tracks the footprint of the computing device 110. However, the footprint of the plate 135 may differ from the computing device 110.

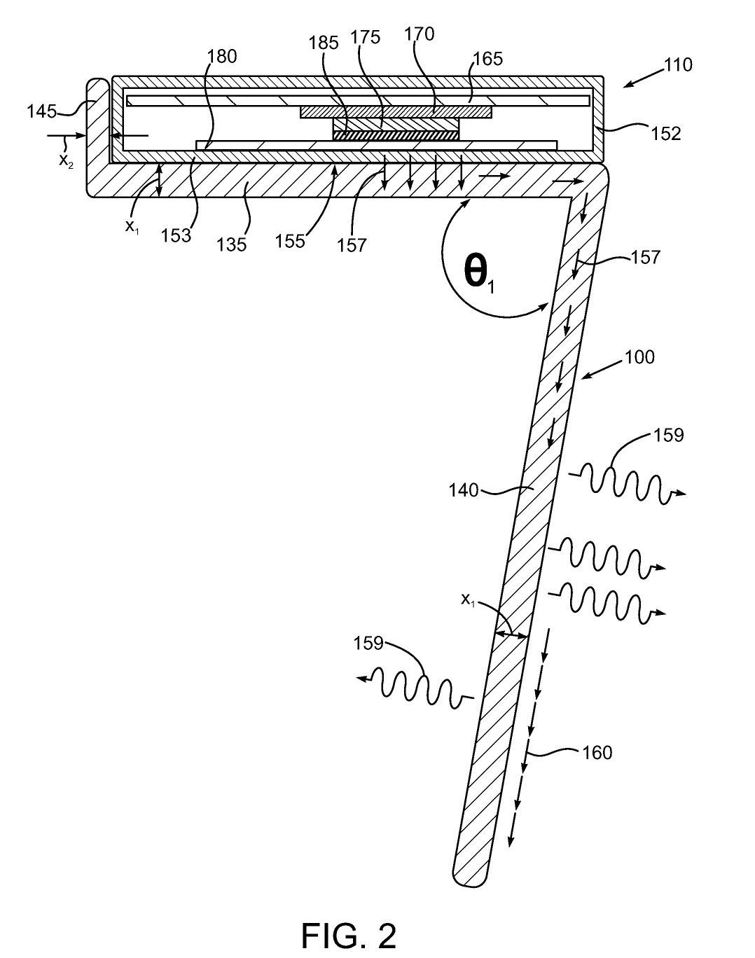

Additional details of the stand 100 and the computing device 110 may be understood by referring now also to FIG. 2, which is a sectional view of FIG. 1 taken at section 2-2. As is shown in FIG. 2, the computing device 110 includes a chassis 152. The chassis 152 includes a lower wall 153 that is seated on the upper surface 155 of the support plate 135 so that the principal mechanism to transfer heat from the computing device 110 to the stand 100 is by way of conduction from the lower wall 153 to the upper surface 155. As described in conjunction with a subsequent figure, a thermal interface material (TIM) (not shown) may be provided between the computing device 110 and the upper surface 155 of the support plate 135 to facilitate conductive heat transfer. The conductive heat 157 is ultimately transferred from the stand 100 to the ambient environment by way of radiation 159 and convection 160, natural and/or forced. One or more of the components of the stand 100, such as the support plate 135, the wall 140 and the optional lip 145, may be composed of a variety of thermally conducting materials, such as, for example, copper, aluminum, gold, silver, alloys of these or other types of materials. In this illustrative embodiment, the support plate 135 and the wall 140 may have some thickness x₁ and the lip 145 may have some thickness x₂ that is smaller than the thickness x₁. However, it should be understood that the plate 135, the wall 140 and the lip 145 may be fabricated with the same thicknesses, with different thicknesses or with even varying thicknesses across the span of a given piece, such as the plate 135 or the wall 140. The rate of transfer of conductive heat 157 is directly proportional to, among other things, the thermal conductivities of the chassis wall 153 and the stand 100 and the area of the stand 100 through which heat flows, given by x₁y. The rates of transfer of radiative heat 159 and convective heat 160 are directly proportional to the surface area of the stand 100. The heat absorbing, radiating and convective capabilities of the stand 100 will generally be increased by enlarging portions or all of the stand 100. However, such enlargements may result in increased material costs and weight. The stand 100 and any disclosed alternatives may be formed by stamping, forging, casting, molding or machining or some combination of such processes as desired.

In this illustrative embodiment, the wall 140 is integrally formed with the support plate 135 and oriented at an angle θ₁ relative to the support plate 135 as shown. The angle θ₁ may be slightly less than 90° to facilitate a type of engagement of the stand 100 with another component to be described in conjunction with the next figure. The computing device 10 is shown positioned on the support plate 135 near but not in physical contact with the supporting lip 145. However, physical contact with the lip 145 is envisioned and would actually facilitate better conductive heat transfer from the computing device 110 to the stand 100.

As noted above, the computing device 110 can take on a virtually limitless number of types of configurations. For the purposes of discussion, the illustrated embodiment of the computing device 110 may be a portable computing device that includes a variety of internal features. For example, the chassis 152 of the computing device 110 may house a system board 165. A variety of components may be mounted on the system board 165. For example, a packaged processor that includes a package substrate 170 and a semiconductor chip or integrated circuit 175 may be mounted on the system board 165. To provide thermal management for the processor 175, a heat spreader 180 may be placed in thermal contact with the semiconductor chip 175 by way of the thermal interface material layer 185. The heat spreader 180 may be composed of a variety of thermally conducting materials, such as, for example, copper, aluminum, gold, silver, graphite or other types of materials. The thermal interface material 185 may be composed of well-known polymer materials such as silicone paste, thermal greases, gap pads or other types of TIMS. The semiconductor chip 175 may be any of a myriad of different types of semiconductor chips such as microprocessors, graphics processors, combined microprocessor/graphics processors sometimes known as application processing units, application specific integrated circuits, memory devices, systems on a chip, optical devices, passive components, interposers, or other devices and mounted to other devices, such as circuit boards as desired. The heat spreader 180 is in thermal contact with the lower wall 153 of the chassis 152. This contact may be direct or there may be another TIM (not shown) positioned between the heat spreader 180 and the lower wall 153. Optionally, the heat spreader 180 may be positioned above the lower wall 153 to leave an air gap.

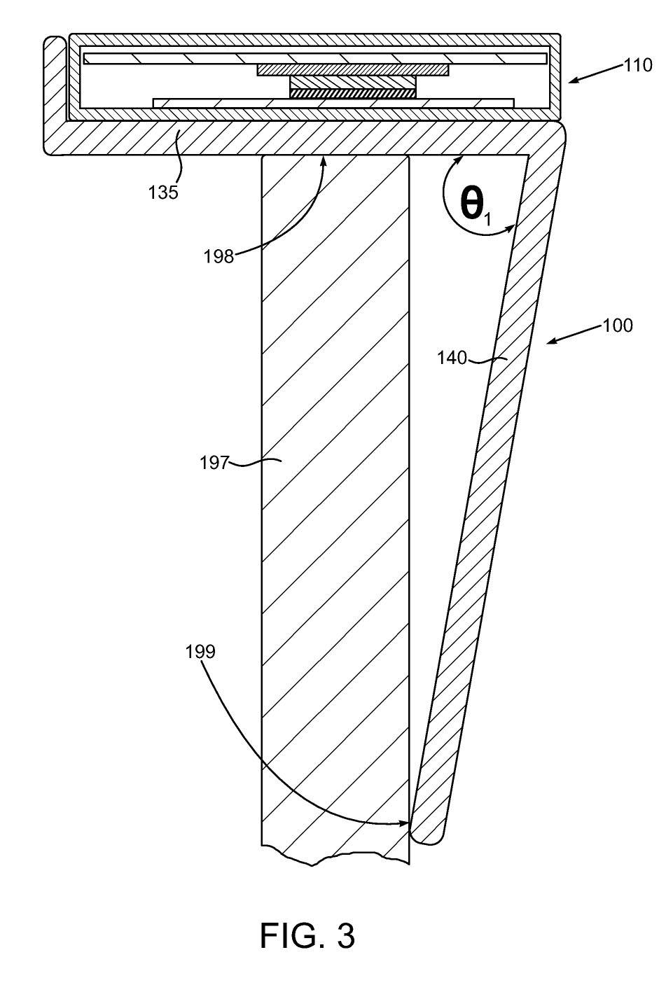

Attention is now directed to FIG. 3, which is a sectional view like FIG. 2, but depicting the stand 100 and the computing device 110 positioned on a member 197, which may be an electronic device 197 or something else. Exemplary electronic devices include, for example, a flat panel television, a video monitor or virtually any other type of electronic device. It may be desirable, for example, to electronically connect the computing device 110 to the electronic device 197 to perform some action, such as to allow the play of a video game or the display of other content on the electronic device 197. Here, the spatial orientation of the wall 140 relative to the plate 135 with the angle θ₁ enables the support plate 135 to seat on the upper surface 198 of the electronic device 197 while the lower end of the wall 140 bears against the side surface 199 of the electronic device 197. In this way, the stand 100 may rest on the electronic device 197 in a stable manner.

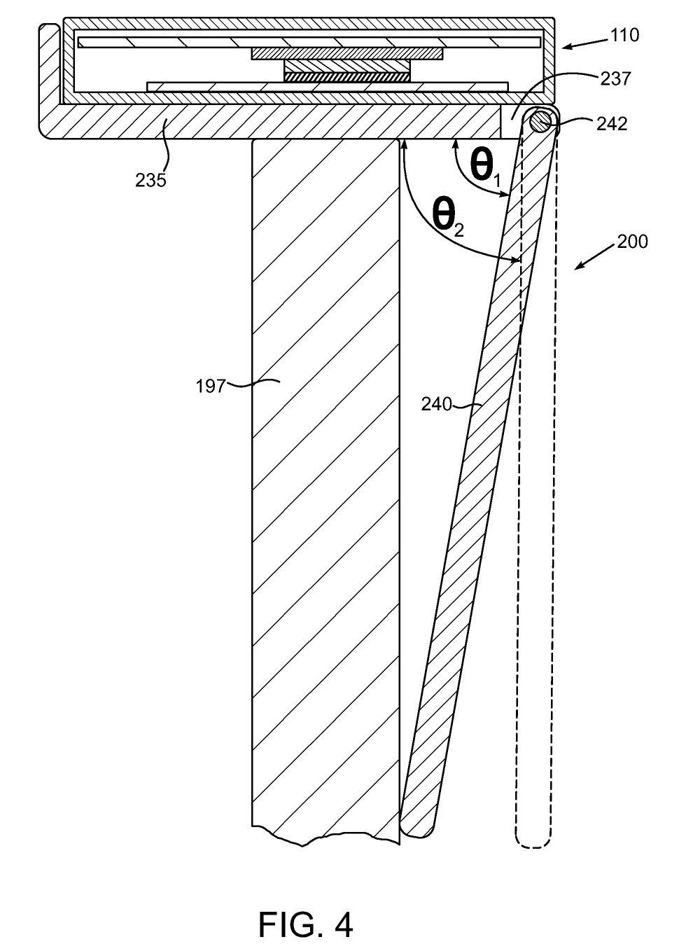

An alternate exemplary embodiment of a stand 200 may be understood by referring now to FIG. 4, which is a sectional view like FIG. 3, but depicts the stand 200 seated on the electronic device 197. In this illustrative embodiment, the computing device 110 may be both mechanically supported and thermally managed by way of the stand 200 substantially as described above. However, the support plate 235 and the wall 240 are pivotally joined by way of a pivot pin 242 such that the wall 240 may be pivoted from angle θ₁ to angle θ₂ and thus from the position shown to the alternate position depicted in dash. In this way, the wall 240 may be pivoted through the angular range θ₂-θ₁ so that the stand 200 can be seated on electronic devices with varying widths. For example, a wider version of the electronic device 197 than that depicted in FIG. 4 might call for a different angular position of the wall 240 versus a thinner one. Note that in this illustrative embodiment, the wall 240 is pivotally connected by way of the pivot pin 242. However, other types of pivoting connections may be used as well. In addition, a friction sleeve or other friction device (not shown) may be incorporated into the pivotal connection of the wall 240 to the support plate 235 so that the wall 240 may be moved to a desired angular position and the friction sleeve (not shown) will hold that angular position. Optionally, a spring (not shown) may be used to bias the wall 240 toward position θ₁. Note that the support plate 235 will include a cut out 237 that is designed to facilitate the rotational movement of the wall 240.

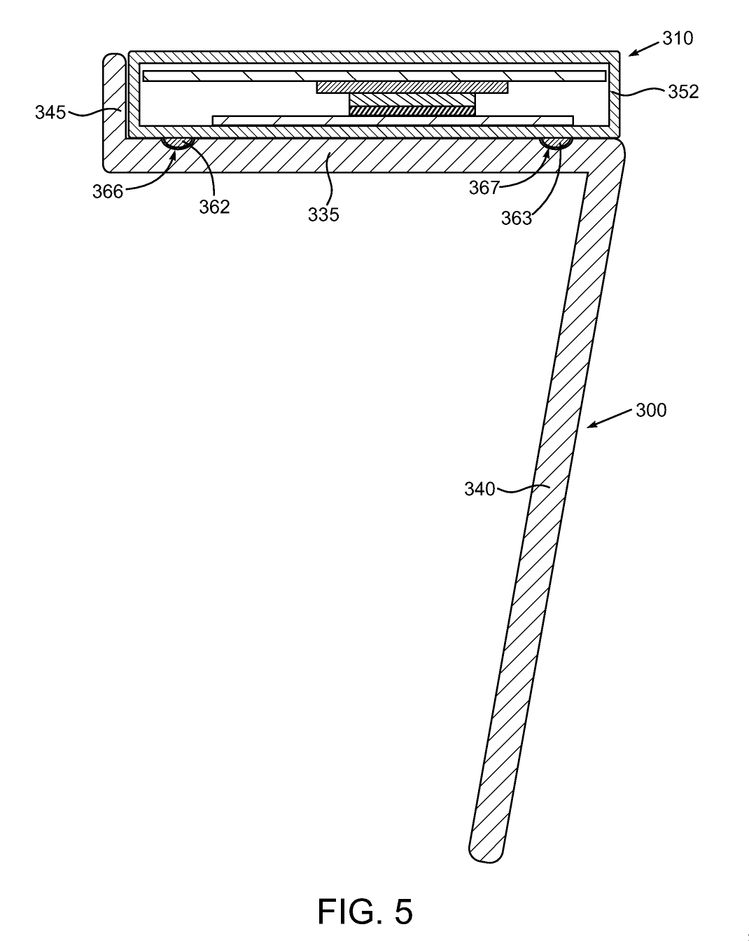

Attention is now directed to FIG. 5, which is a sectional view like FIG. 3, but depicting an alternate exemplary embodiment of a stand 300, which includes a support plate 335 and a wall 340 connected thereto. The plate 335 and the wall 340 as well as an optional lip 345 may be configured substantially as described above in conjunction with the other illustrative embodiments with a notable exception. Some types of computing devices, such as the computing device 310, may include a chassis 352 that has one or more support pads 362 and 363 composed of rubber(s), plastic(s) or other materials. With these types of pad-supported devices, it is still desirable to establish a substantial area of conductive heat transfer thermal contact between the chassis 352 and the support plate 335. Accordingly, the support plate 335 may be provided with one or more dimples 366 and 367 that are designed to allow the chassis 352 to be seated on the support plate 335 with the support pads 362 and 363 seating in the dimples 366 and 367, respectively, so that the gap between the chassis 352 and the support plate 335 is eliminated or substantially reduced. If still present, a gap may be filled with a TIM (not shown). The number arrangement and size and shapes of the dimples 366 and 367 may be tailored according to the spatial arrangement of whatever support tabs 362 and 363 are present on the computing device 310.

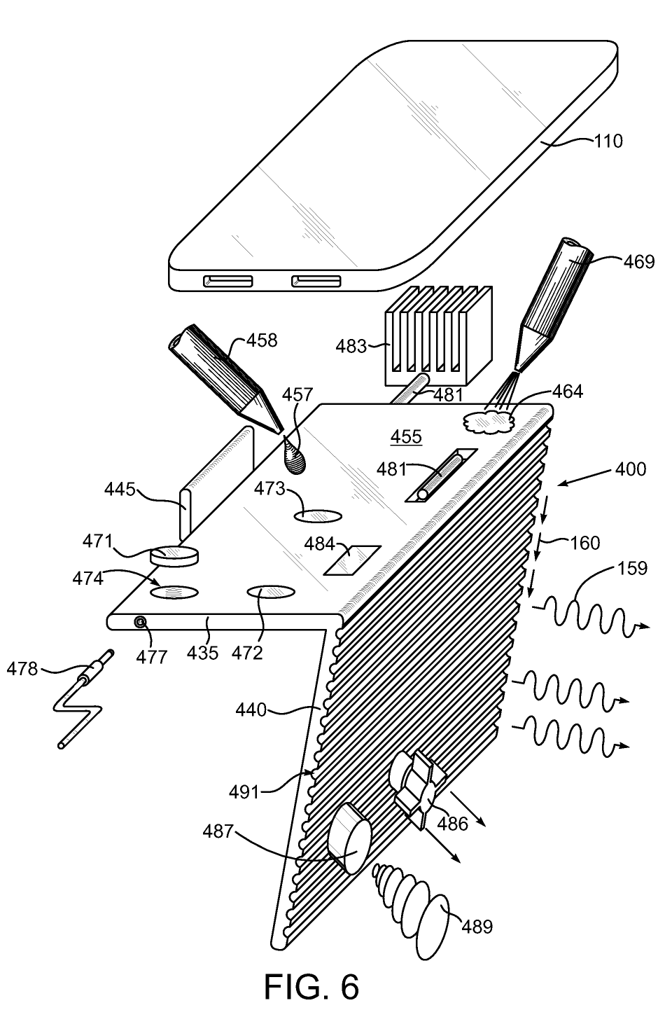

Attention is now turned to FIG. 6, which is a pictorial view of an alternate exemplary stand 400 upon which the computing device 110 may be seated. The stand 400 may include a support plate 435, a support wall 440, an optional support lip 445 configured as disclosed elsewhere herein. In addition, other features may be included not only with the stand 400 but also with any disclosed alternatives, such as the stands 100, 200 and 300. For example, the upper surface 455 of the support plate 435 may be coated with a TIM 457. The TIM 457 may be co-extensive with the totality of the interface between the computing device 110 and the upper surface 455 or only cover some lesser portion. A suitable applicator 458 may be used to apply the TIM 457. The TIM 457 may be composed of well-known silicone material, thermal greases, thermal pads or other TIM materials.

In addition, the external surfaces of the stand 400 may be provided with a suitable thermally emissive coating 464, again by way of a suitable applicator 469 or otherwise. The coating 464 may be designed to facilitate the transfer of radiative heat 159 from the stand 400 to the ambient environment. The coating 464 may be composed of a variety of materials. For example, and in the event that the stand 400 is composed of aluminum, the coating 464 may be composed of anodized aluminum. Optionally, dark pigmented thermal paints or other materials may be used for the coating 464. FIG. 6 depicts application of the coating 464 to a small portion of this support plate 435. However, it is envisioned that the entire external surface or at least portions thereof of the stand 400 may be suitably coated in this way.

In addition, the stand 400 may be provided with one or more thermoelectric coolers 471, 472 and 473. In this illustrative embodiment, the thermoelectric coolers 471, 472 and 473 may be positioned in the support plate 435. The thermoelectric coolers 471, 472 and 473 may be fitted to the stand 400 by way of drop-in openings 474 as shown or by other means. The thermoelectric coolers 471, 472 and 473 may number more or less than three and may be provided with the requisite electrical power by way of a power port 477, which can be serviced by a power supply plug 478 as shown. The power port 477 can power other electrical devices associated with the stand 400 (potentially including the device 110 by way of inductive or other wireless charging).

In addition, one or more heat pipes 481 may be connected to the stand 400. One of the heat pipes 481 may be connected to a heat sink 483 and another embedded in the stand 400 as shown. The heat sink 483 may configured as a radiative spreader or a vapor chamber or both. Multiple heat pipes 481 and heat sinks 483 may be used and they may be arranged in a myriad of different ways. As with the heat pipes 481, one or more vapor chambers 484 may be fitted to the stand. Any of these thermoelectric coolers 471, 472, etc., heat pipes 481 and/or vapor chambers 484 may positioned near anticipated hot spots of the computing device 110. Indeed, the computing device 110 may be thermally mapped and the stand 400 tailored accordingly.

Different types of fans could be added to the stand 400, such as a mechanical fan(s) 486, a piezoelectic fan(s) 487 or other types. A purely mechanical fan 486 will have some acoustic signature, but a piezoelectric fan(s) 487 emitting low frequency pulses 489 to move air may not. For example, pulses in the 200 to 1000 Hz range should be inaudible.

Finally, one or more external surfaces of the stand 400 may be textured to increase the surface area available for transfer of radiative heat 159 and convective heat 160. Here, corrugations 491 are added to the wall 440, but other texturing may be used.

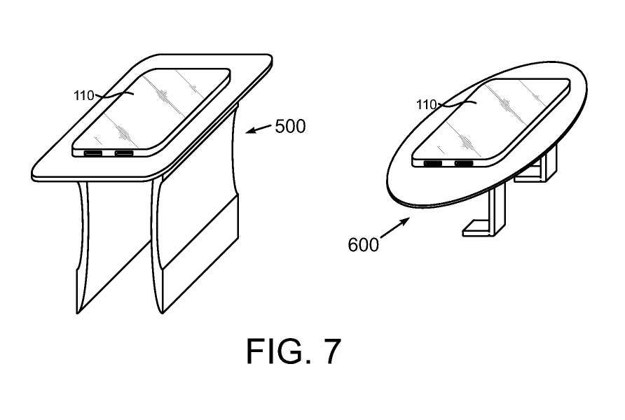

As noted elsewhere herein, many configurations may be used for a thermal management stand. FIG. 7 depicts a couple of additional exemplary embodiments of stands 500 and 600 that are operable to support and thermally manage the computing device 110. As a consequence of stands 100, 400, 500 and/or 600 (or other embodiments of the invention), additional heat transfer may occur. Consequently, the computing device 110 may operate cooler than would otherwise be the case enabling processor 175 and other components within to operate at lower temperatures or operate at higher processing performance states than would otherwise be possible.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of thermally managing a portable computing device, comprising:
placing the portable computing device on a stand having a support plate with a first surface wherein a second surface of the portable computing device contacts the first surface of the support plate;
transferring heat from the computing device to the support plate by conduction; and
transferring heat received by the stand from the computing device to the ambient environment.

2. The method of claim 1, wherein the stand comprises a first wall coupled to the support plate and adapted to bear against a member supporting the stand.

3. The method of claim 2, wherein the member comprises an electronic device, the method comprising placing the stand on the electronic device.

4. The method of claim 2, wherein the first wall is pivotally coupled to the support plate.

5. The method of claim 1, comprising placing a thermal interface material between the first surface and the second surface.

6. The method of claim 1, wherein the stand comprises at least one thermoelectric cooler.

7. The method of claim 1, comprising coating at least a portion of the stand with a thermally emissive coating.

8. The method of claim 1, comprising coupling a heat sink to the stand.

9. A method of manufacturing a stand for supporting and thermally managing a portable computing device having a first surface, comprising:
providing a support plate having a second surface to contact the first surface of the computing device and transfer heat from the computing device by conduction; and
coupling a first wall to the support plate, the wall being adapted to bear against a member supporting the stand; and
wherein the stand is operable to transfer heat received from the computing device to the ambient environment by radiation.

10. The method of claim 9, wherein the first wall is pivotally coupled to the support plate.

11. The method of claim 9, comprising coupling a second wall to the support plate, the second wall adapted to bear against the electronic device.

12. The method of claim 9, comprising coupling at least one thermoelectric cooler to the stand.

13. The method of claim 9, comprising coating at least a portion of the stand with a thermally emissive coating.

14. The method of claim 9, comprising coupling a heat sink to the stand.

15. The method of claim 13, wherein the heat sink comprises a heat pipe.

16. A stand for supporting and thermally managing a portable computing device having a first surface, comprising:
a support plate having a second surface to contact the first surface of the computing device and transfer heat from the computing device by conduction; and
the stand operable to transfer heat received from the computing device to the ambient environment.

17. The stand of claim 16, comprising a first wall coupled to the support plate and adapted to bear against a member.

18. The stand of claim 17, wherein the first wall is pivotally coupled to the support plate.

19. The stand of claim 16, comprising at least one thermoelectric cooler coupled to the stand.

20. The stand of claim 16, comprising a heat sink.
